(19) United States
(12) Patent Application Publication
(10) Pub. No.: US 2025/0055448 A1
(43) Pub. Date: Feb. 13, 2025

(54) SWITCH DEVICE

(71) Applicants: Kabushiki Kaisha Toshiba, Tokyo (JP); Toshiba Electronic Devices & Storage Corporation, Tokyo (JP)

(72) Inventors: Hideki OKU, Kawasaki Kanagawa (JP); Tadashi KANEMARU, Fuchu Tokyo (JP)

(21) Appl. No.: 18/600,302

(22) Filed: Mar. 8, 2024

(30) Foreign Application Priority Data
Aug. 8, 2023 (JP) 2023-129405

(51) Int. Cl. H03K 17/00; H03K 17/284

(52) U.S. Cl. CPC H03K 17/002; H03K 17/284

(57) ABSTRACT

First and second semiconductor devices include a first side and first to sixth terminals, couples the first terminal to the second terminal while the sixth, fourth and fifth terminals are receiving first, second and third voltages, and couples the first terminal to the third terminal while the sixth, fourth and fifth terminals are receiving fourth, third and second voltages. A first delay circuit supplies, to the third terminal of the second semiconductor device, a delayed signal at an input end coupled to the second terminal of the first semiconductor device. The first conductor is coupled to the fourth terminal of the first semiconductor device and the fifth terminal of the second semiconductor device. The second conductor is coupled to the fifth terminal of the first semiconductor device and the fourth terminal of the second semiconductor device. The first sides of the first and second semiconductor devices face each other.

### CROSS-REFERENCE TO RELATED APPLICATION

This application is based upon and claims the benefit of priority from Japanese Patent Application No. 2023-129405, filed Aug. 8, 2023, the entire contents of which are incorporated herein by reference.

### FIELD

Embodiments relate generally to a switch device.

### BACKGROUND

Multiple input multiple output (MIMO) is known as a technology used in wireless communication. A transmitter-receiver that supports MIMO includes multiple antennas and multiple switch circuits. The transmitter-receiver uses a phase switch device to generate, from a common signal, multiple transmission signals having phases differing from each other and transmits the transmission signals from multiple antennas. The transmitter-receiver includes the same number of phase switch devices as the number of antennas.

Improved MIMO performance may be realized by increasing the number of antennas. As the number of antennas increases, the number of phase switch devices needed also increases. Thus, it is required that the coupling between the components of each of the phase switch devices be simple in order to manufacture a transmitter-receiver efficiently.

### BRIEF DESCRIPTION OF THE DRAWINGS

FIG. 1 shows functional blocks of a transmitter-receiver including a switch device of a first embodiment and coupling between the functional blocks.

FIG. 2 shows functional blocks of the switch device of the first embodiment and coupling between the functional blocks.

FIG. 3 shows components of a switch circuit of the switch device of the first embodiment and coupling between the components.

FIG. 4 shows a relationship between the input and the output performed by a logic circuit included in the switch device of the first embodiment.

FIG. 5 shows an example of a structure of the switch circuit of the switch device of the first embodiment.

FIG. 6 shows an example of a partial structure of the switch device of the first embodiment.

FIG. 7 shows an example of a structure of a switch circuit of a switch device of a second embodiment.

FIG. 8 shows an example of a partial structure of the switch device of the second embodiment.

FIG. 9 shows an example of a structure of a switch circuit of a switch device of a third embodiment.

FIG. 10 shows an example of a partial structure of the switch device of the third embodiment.

FIG. 11 shows an example of a structure of a switch circuit of a switch device of a fourth embodiment.

FIG. 12 shows an example of a partial structure of the switch device of the fourth embodiment.

### DETAILED DESCRIPTION

In general, according to one embodiment, a switch device includes: a first semiconductor device and a second semiconductor device, a first delay circuit; a first conductor; and a second conductor. Each of the first semiconductor device and the second semiconductor device includes: a first side; a second side and a third side facing each other; a first terminal; a second terminal facing the second side; a third terminal facing the third side; a fourth terminal and a fifth terminal arranged along the first side; and a sixth terminal. Each of the first semiconductor device and the second semiconductor device couples the first terminal to the second terminal while the sixth terminal is receiving a first voltage, the fourth terminal is receiving a second voltage, and the fifth terminal is receiving a third voltage. Each of the first semiconductor device and the second semiconductor device couples the first terminal to the third terminal while the sixth terminal is receiving a fourth voltage, the fourth terminal is receiving the third voltage, and the fifth terminal is receiving the second voltage. The first delay circuit is configured to supply, to the third terminal of the second semiconductor device, a signal obtained by delaying a signal at an input end coupled to the second terminal of the first semiconductor device. The first conductor is coupled to the fourth terminal of the first semiconductor device and the fifth terminal of the second semiconductor device. The second conductor is coupled to the fifth terminal of the first semiconductor device and the fourth terminal of the second semiconductor device. The first side of the first semiconductor device faces the first side of the second semiconductor device. The sixth terminal of the first semiconductor device is coupled to a terminal receiving the first voltage. The sixth terminal of the second semiconductor device is coupled to a terminal receiving the fourth voltage.

Embodiments will now be described with reference to the figures. In order to distinguish components having substantially the same function and configuration in an embodiment or over different embodiments from each other, an additional numeral or letter may be added to the end of each reference numeral or letter. For an embodiment subsequent to an embodiment that has already been described, the description will concentrate mainly on the matters that constitute a difference from the already described embodiment. The entire description of a particular embodiment applies to another embodiment unless an explicit mention is made otherwise, or an obvious elimination is involved.

The specification and the claims, when mentioning that a particular (first) component is “coupled” to another (second) component, intend to cover both the form of the first component directly coupled to the second component and the form of the first component coupled to the second component via one or more components which are always or selectively conductive.

The embodiments will be described using an X-Y-Z orthogonal coordinate system. A plus direction of a vertical axis in a drawing may be referred to as an upper side, and a minus direction of the vertical axis may be referred to as a lower side. A plus direction of a horizontal axis in a drawing may be referred to as a right side, and a minus direction of the horizontal axis may be referred to as a left side. That is, in a plan view showing an X-Y plane (referred to as an X-Y plane view, the same applying hereinafter), an upper side of the X-Y plane represents a +Y direction, a lower side of the X-Y plane represents a −Y direction, a right side of the X-Y plane represents a +X direction, and a left side of the X-Y plane represents a −X direction.

### 1. First Embodiment

1.1. Configuration (Structure)

FIG. 1 shows functional blocks of a transmitter-receiver including a switch device of a first embodiment and coupling between the functional blocks. As shown in FIG. 1, a transmitter-receiver 10 includes a data processing circuit 1, a transceiver 2, an amplifier circuit 3, multiple switch devices 4, and multiple antennas 5. FIG. 1 shows an example in which four switch devices and four antennas are included in the transmitter-receiver 10, and the descriptions below follow this example.

The data processing circuit 1 is a circuit that generates data to be transmitted by the transmitter-receiver 10. The data processing circuit 1 may be realized as a single semiconductor chip or may be a circuit formed on a semiconductor substrate.

The transceiver 2 generates a signal to be transmitted by the transmitter-receiver 10. The transceiver 2 receives data from the data processing circuit 1 and generates a transmission signal by modulating the data. The transceiver 2 may be realized as a single semiconductor chip or may be a circuit formed on a semiconductor substrate.

The amplifier circuit 3 is a circuit that amplifies a signal received by the amplifier circuit 3. The amplifier circuit 3 receives a transmission signal from the transceiver 2 and amplifies the received transmission signal to be transmitted. The amplifier circuit 3 may be realized as a single semiconductor chip or may be a circuit formed on a semiconductor substrate.

Each switch device 4 is a circuit that changes a phase of a signal received by the switch device 4. The switch device 4 receives a signal from the amplifier circuit 3 and changes the phase of the received signal by only the magnitude of one phase dynamically selected from among multiple phases. Each switch device 4 is realized as a device including a semiconductor chip and is, for example, a semiconductor device (or a semiconductor module) that includes a semiconductor chip, a resin enclosing the semiconductor chip, and a terminal to be electrically coupled to an external device.

Each antenna 5 transmits a signal received by the antenna 5 to the outside of the transmitter-receiver 10 by radio. Each antenna 5 is coupled to one switch device 4.

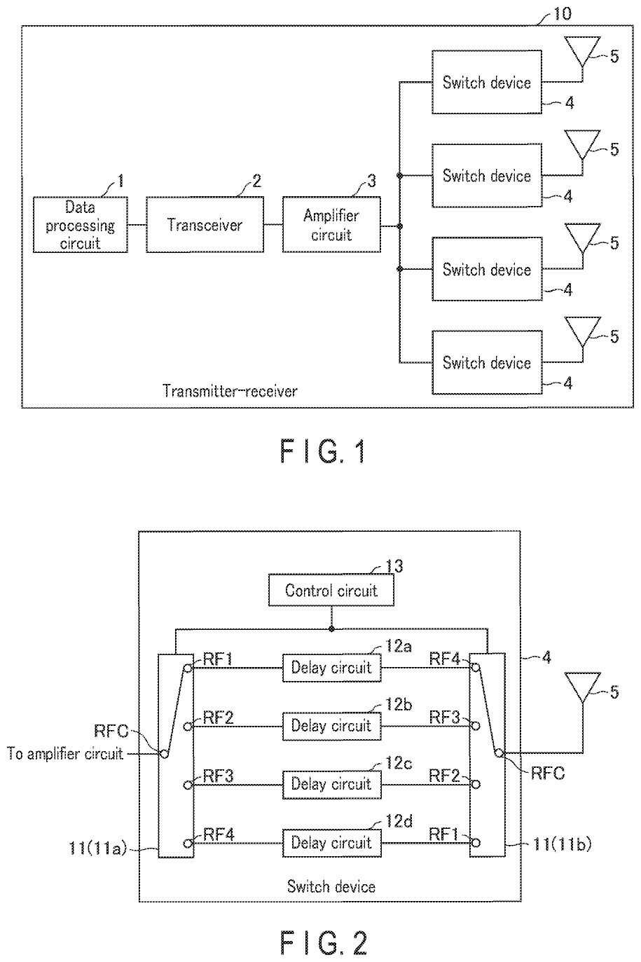

FIG. 2 shows functional blocks of the switch device of the first embodiment and coupling between the functional blocks. As shown in FIG. 2, the switch device 4 includes two switch circuits 11 (11a and 11b), multiple delay circuits 12 (12a, 12b, 12c, and 12d), and a control circuit 13. FIG. 2 shows an example in which four delay circuits 12 are included, and the descriptions below follow this example.

The switch circuit 11 includes a terminal RFC and multiple terminals RF (RF1, RF2, RF3, and RF4). The number of terminals RF coincides with the number of delay circuits 12. Under the control executed by the control circuit 13, the switch circuit 11 electrically couples the terminal RFC to one terminal dynamically selected from among the terminals RF1, RF2, RF3, and RF4.

The switch circuits 11a and 11b are the same switch circuits. The switch circuit 11a is coupled to the amplifier circuit 3 at the terminal RFC. The switch circuit 11a is coupled to an input end of the delay circuit 12a at the terminal RF1. The switch circuit 11a is coupled to an input end of the delay circuit 12b at the terminal RF2. The switch circuit 11a is coupled to an input end of the delay circuit 12c at the terminal RF3. The switch circuit 11a is coupled to an input end of the delay circuit 12d at the terminal RF4.

The switch circuit 11b is coupled to one antenna 5 at the terminal RFC. The switch circuit 11b is coupled to an output end of the delay circuit 12d at the terminal RF1. The switch circuit 11b is coupled to an output end of the delay circuit 12c at the terminal RF2. The switch circuit 11b is coupled to an output end of the delay circuit 12b at the terminal RF3. The switch circuit 11b is coupled to an output end of the delay circuit 12a at the terminal RF4.

The delay circuit 12 is a circuit that delays, by a predetermined phase, a signal received at the input end and outputs the delayed signal from the output end. The delay circuit 12a, the delay circuit 12b, the delay circuit 12c, and the delay circuit 12d delay received signals by phases differing from each other.

The control circuit 13 is a circuit that controls the operation of the switch device 4. The control circuit 13 generates a control signal that controls the switch circuits 11 based on the operation that should be performed by the switch device 4, that is, based on the amount of delay of the signal based on the operation, and outputs the control signal.

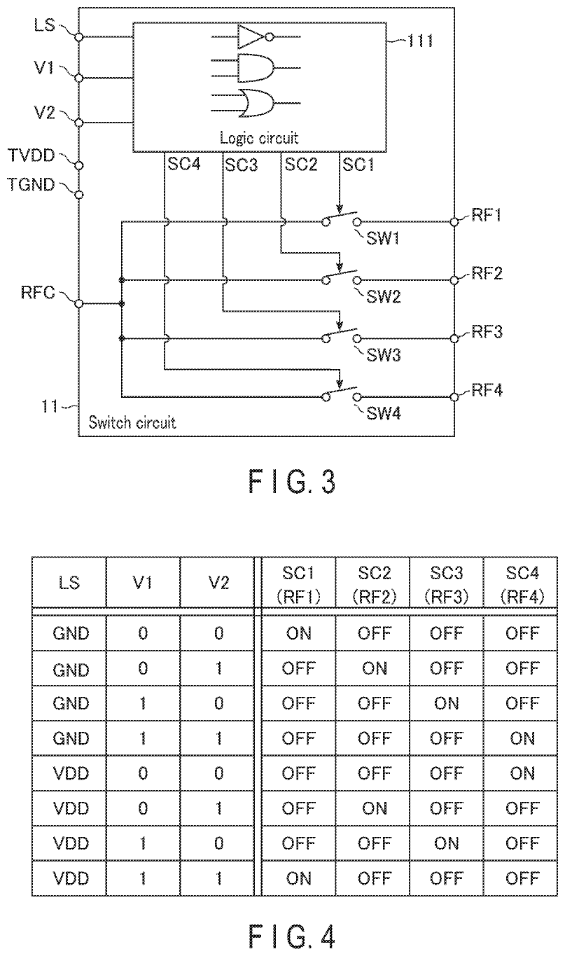

FIG. 3 shows components of a switch circuit of the switch device of the first embodiment and coupling between the components. As shown in FIG. 3, the switch circuit 11 includes switches SW1, SW2, SW3, and SW4, and a logic circuit 111. The switch circuit 11 not only includes the terminals RFC, RF1, RF2, RF3, and RF4, as described above with reference to FIG. 2, but also includes terminals LS, V1, V2, TVDD, and TGND.

The switch SW1 receives a control signal SC1 and electrically connects or disconnects both ends of the switch SW1 based on the control signal SC1. The switch SW1 is coupled between the terminal RFC and the terminal RF1. The switch SW1 is, for example, a metal oxide semiconductor field effect transistor (MOSFET).

The switch SW2 receives a control signal SC2 and electrically connects or disconnects both ends of the switch SW2 based on the control signal SC2. The switch SW2 is coupled between the terminal RFC and the terminal RF2. The switch SW2 is, for example, a MOSFET.

The switch SW3 receives a control signal SC3 and electrically connects or disconnects both ends of the switch SW3 based on the control signal SC3. The switch SW3 is coupled between the terminal RFC and the terminal RF3. The switch SW3 is, for example, a MOSFET.

The switch SW4 receives a control signal SC4 and electrically connects or disconnects both ends of the switch SW4 based on the control signal SC4. The switch SW4 is coupled between the terminal RFC and the terminal RF4. The switch SW4 is, for example, a MOSFET.

The logic circuit 111 generates the control signals SC1, SC2, SC3, and SC4 based on a voltage received at the terminals LS, V1, and V2. The logic circuit 111 may have any configuration, provided that the logic circuit 111 can generate the control signals SC1, SC2, SC3, and SC4 (described later with reference to FIG. 4) based on a voltage received at the terminals LS, V1, and V2. The logic circuit 111 includes, for example, multiple logic gates.

FIG. 4 shows a relationship between the input and the output performed by the logic circuit included in the switch device of the first embodiment. Each of the terminals V1 and V2 receives one voltage dynamically selected from among voltages with two different magnitudes. One of the voltages is referred to as a “0” voltage, and is represented by “0” in FIG. 4. The other of the voltages is referred to as a “1” voltage, and is represented by “1” in FIG. 4.

Each of the control signals SC1, SC2, SC3, and SC4 takes either one of the two differing magnitudes. In FIG. 4 and the descriptions below, the state in which the control signal SC1 has a voltage that keeps the switch SW1 on, the state in which the control signal SC2 has a voltage that keeps the switch SW2 on, the state in which the control signal SC3 has a voltage that keeps the switch SW3 on, and the state in which the control signal SC4 has a voltage that keeps the switch SW4 on are referred to as the control signals SC1, SC2, SC3, and SC4 having the “ON” level. The state in which the control signal SC1 has a voltage that keeps the switch SW1 off, the state in which the control signal SC2 has a voltage that keeps the switch SW2 off, the state in which the control signal SC3 has a voltage that keeps the switch SW3 off, and the state in which the control signal SC4 has a voltage that keeps the switch SW4 off are referred to as the control signals SC1, SC2, SC3, and SC4 having the “OFF” level. In FIG. 4, the “ON” level is indicated as “ON”. In FIG. 4, the “OFF” level is indicated as “OFF”.

While the terminal LS is receiving a ground voltage GND, the terminal V1 is receiving the “0” voltage, and the terminal V2 is receiving the “0” voltage, the control signal SC1 has the “ON” level, the control signal SC2 has the “OFF” level, the control signal SC3 has the “OFF” level, and the control signal SC4 has the “OFF” level. Thus, the terminal RFC is coupled only to the terminal RF1 among the terminals RF1, RF2, RF3, and RF4 via the switch SW1 that is on. That is, the terminal RF1 is selected.

While the terminal LS is receiving a ground voltage GND, the terminal V1 is receiving the “0” voltage, and the terminal V2 is receiving the “1” voltage, the control signal SC1 has the “OFF” level, the control signal SC2 has the “ON” level, the control signal SC3 has the “OFF” level, and the control signal SC4 has the “OFF” level. Thus, the terminal RFC is coupled only to the terminal RF2 among the terminals RF1, RF2, RF3, and RF4 via the switch SW2 that is on. That is, the terminal RF2 is selected.

While the terminal LS is receiving a ground voltage GND, the terminal V1 is receiving the “1” voltage, and the terminal V2 is receiving the “0” voltage, the control signal SC1 has the “OFF” level, the control signal SC2 has the “OFF” level, the control signal SC3 has the “ON” level, and the control signal SC4 has the “OFF” level. Thus, the terminal RFC is coupled only to the terminal RF3 among the terminals RF1, RF2, RF3, and RF4 via the switch SW3 that is on. That is, the terminal RF3 is selected.

While the terminal LS is receiving a ground voltage GND, the terminal V1 is receiving the “1” voltage, and the terminal V2 is receiving the “1” voltage, the control signal SC1 has the “OFF” level, the control signal SC2 has the “OFF” level, the control signal SC3 has the “OFF” level, and the control signal SC4 has the “ON” level. Thus, the terminal RFC is coupled only to the terminal RF4 among the terminals RF1, RF2, RF3, and RF4 via the switch SW4 that is on. That is, the terminal RF4 is selected.

While the terminal LS is receiving a power supply voltage VDD, the terminal V1 is receiving the “0” voltage, and the terminal V2 is receiving the “0” voltage, the control signal SC1 has the “OFF” level, the control signal SC2 has the “OFF” level, the control signal SC3 has the “OFF” level, and the control signal SC4 has the “ON” level. Thus, the terminal RFC is coupled only to the terminal RF4 among the terminals RF1, RF2, RF3, and RF4 via the switch SW4 that is on. That is, the terminal RF4 is selected.

While the terminal LS is receiving a power supply voltage VDD, the terminal V1 is receiving the “0” voltage, and the terminal V2 is receiving the “1” voltage, the control signal SC1 has the “OFF” level, the control signal SC2 has the “ON” level, the control signal SC3 has the “OFF” level, and the control signal SC4 has the “OFF” level. Thus, the terminal RFC is coupled only to the terminal RF2 among the terminals RF1, RF2, RF3, and RF4 via the switch SW2 that is on. That is, the terminal RF2 is selected.

While the terminal LS is receiving a power supply voltage VDD, the terminal V1 is receiving the “1” voltage, and the terminal V2 is receiving the “0” voltage, the control signal SC1 has the “OFF” level, the control signal SC2 has the “OFF” level, the control signal SC3 has the “ON” level, and the control signal SC4 has the “OFF” level. Thus, the terminal RFC is coupled only to the terminal RF3 among the terminals RF1, RF2, RF3, and RF4 via the switch SW3 that is on. That is, the terminal RF3 is selected.

While the terminal LS is receiving a power supply voltage VDD, the terminal V1 is receiving the “1” voltage, and the terminal V2 is receiving the “1” voltage, the control signal SC1 has the “ON” level, the control signal SC2 has the “OFF” level, the control signal SC3 has the “OFF” level, and the control signal SC4 has the “OFF” level. Thus, the terminal RFC is coupled only to the terminal RF1 among the terminals RF1, RF2, RF3, and RF4 via the switch SW1 that is on. That is, the terminal RF1 is selected.

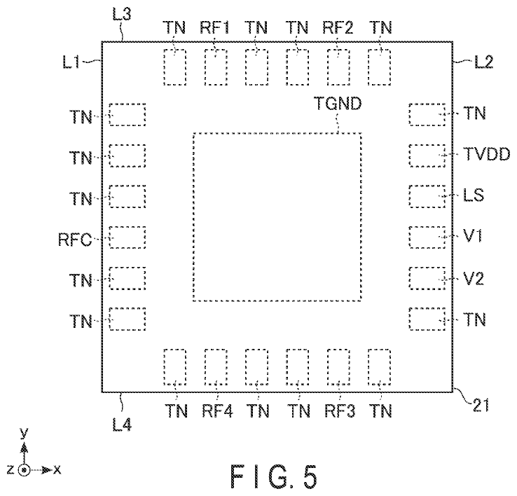

FIG. 5 shows an example of a structure of the switch circuit of the switch device of the first embodiment. The switch circuit 11 is realized as a semiconductor device 21. FIG. 5 and the subsequent figures indicate, using broken lines, elements shown in a transparent manner.

As shown in FIG. 5, the semiconductor device 21 extends over an X-Y plane and has a quadrilateral shape. As an example, the semiconductor device 21 has a rectangular shape.

The semiconductor device 21 includes terminals RFC, RF1, RF2, RF3, RF4, LS, V1, V2, TVDD, TGND, and TN. The terminals RFC, RF1, RF2, RF3, RF4, LS, V1, V2, TVDD, TGND, and TN are arranged on a lower surface of the semiconductor device 21, that is, arranged on a surface of the semiconductor device 21 on the side in the −Z direction. The terminals RFC, RF1, RF2, RF3, RF4, LS, V1, V2, TVDD, TGND, and TN are arranged along the edge of the semiconductor device 21. In one example, six terminals are arranged at intervals along each side of the semiconductor device 21. The descriptions below follow this example.

Among the four sides of the semiconductor device 21, the side facing the terminal RFC is referred to as a first side L1. A second side L2 is opposed to the first side L1. In one example, the first side L1 and the second side L2 are aligned in the +X direction. Among the four sides of the semiconductor device 21, the side facing the terminal RF1 is referred to as a third side L3. The third side L3 is opposed to a fourth side L4. In one example, the fourth side L4 and the third side L3 are aligned in the +Y direction.

In one example, the terminal RFC is arranged in the fourth position from the third side L3.

The terminals V1, V2, LS, and TVDD face the second side L2. The terminals V1 and V2 are adjacent to each other. In one example, the terminal V1 is arranged in the fourth position from the third side L3, and the terminal V2 is arranged in the fifth position from the third side L3. The terminals LS and TVDD may occupy a position of any of the remaining terminals among the terminals arranged along the second side L2.

The terminals RF1 and RF2 face the third side L3. The terminals RF1 and RF2 may occupy a position of any of the terminals among the terminals arranged along the third side L3. In one example, the terminal RF1 is arranged in the second position from the first side L1, and the terminal RF2 is arranged in the fifth position from the first side L1.

The terminals RF3 and RF4 face the fourth side L4. The terminal RF3 is arranged close to either the first side L1 or the second side L2, whichever the terminal RF2 is closer to. According to the example in which the terminal RF1 is arranged in the second position from the first side L1 and the terminal RF2 is arranged in the fifth position from the first side L1, the terminal RF3 is arranged closer to the second side L2 than to the first side L1. In one example, the terminal RF3 and the terminal RF2 are aligned in the +Y direction.

The terminal RF4 is arranged close to either the first side L1 or the second side L2, whichever the terminal RF1 is closer to. According to the example in which the terminal RF1 is arranged in the second position from the first side L1 and the terminal RF2 is arranged in the fifth position from the first side L1, the terminal RF4 is arranged closer to the first side L1 than to the second side L2. In one example, the terminal RF4 and the terminal RF1 are aligned in the +Y direction.

The terminal TN occupies a position other than the positions of the terminals RFC, V1, V2, LS, TVDD, and TGND. In one example, the terminal TN functions as a ground terminal.

The terminal TGND has a quadrilateral shape and, in one example, has a rectangular shape. The terminal TGND is arranged in the center of the semiconductor device 21.

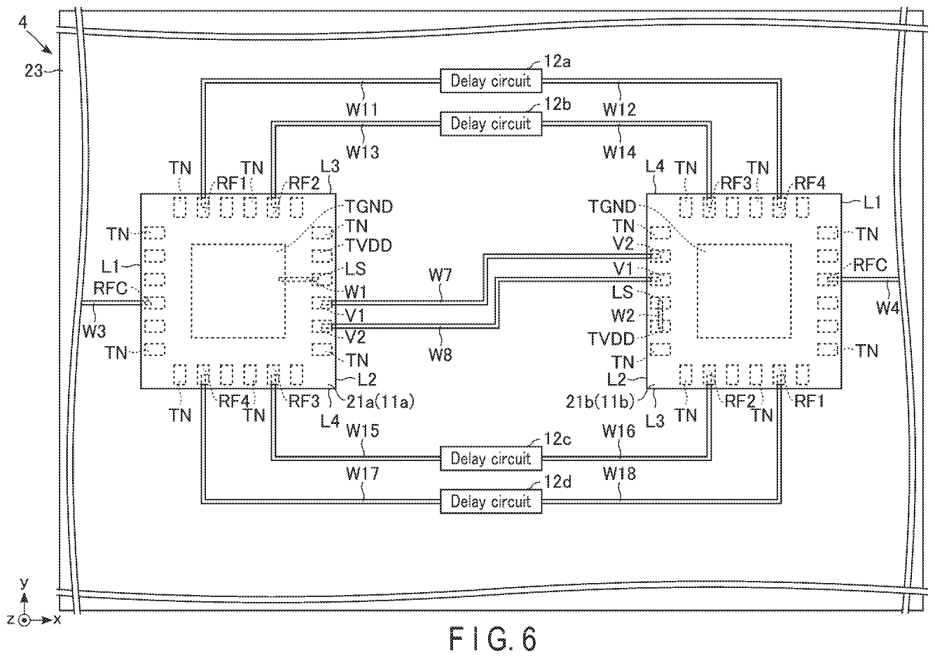

FIG. 6 shows an example of a partial structure of the switch device of the first embodiment and shows the arrangement of the components of the switch device along the X-Y plane. As shown in FIG. 6, the switch device 4 includes semiconductor devices 21 (21a and 21b), a print wiring substrate 23, and interconnects W1, W2, W3, W4, W7, W8, W11, W12, W13, W14, W15, W16, W17, and W18.

The print wiring substrate 23 is a substrate including an insulative substrate. The print wiring substrate 23 extends over the X-Y plane. The print wiring substrate 23 may include multiple layers of insulators and conductors having patterns between the layers of insulators. The control circuit 13 (not shown) is also arranged on the print wiring substrate 23.

The semiconductor device 21a realizes the switch circuit 11a. The semiconductor device 21b realizes the switch circuit 11b. The semiconductor devices 21 are arranged on a surface (upper surface) of the print wiring substrate 23 on the side in the +Z direction. The lower surfaces of the semiconductor devices 21 face the print wiring substrate 23. The semiconductor device 21a and the semiconductor device 21b are arranged in the +X direction.

The semiconductor devices 21a and 21b face opposite directions to each other. That is, the third side L3 of the semiconductor device 21a faces the +Y direction, and the third side L3 of the semiconductor device 21b faces the −Y direction.

The terminals V1 and V2 of the semiconductor device 21a are coupled to the control circuit 13 via the wiring (not shown) provided to the print wiring substrate 23, and receives a voltage from the control circuit 13.

The terminal TVDD receives the power supply voltage VDD. One of the terminal TVDD of the semiconductor device 21a or the terminal TVDD of the semiconductor device 21b is coupled to a node that supplies the power supply voltage VDD via the wiring (not shown) provided to the print wiring substrate 23. The terminal TVDD of the semiconductor device 21a and the terminal TVDD of the semiconductor device 21b are coupled to each other via the wiring (not shown) provided to the print wiring substrate 23.

The terminal TGND receives the ground voltage GND. The terminal TGND of the semiconductor device 21a and the terminal TGND of the semiconductor device 21b are each coupled to a node that supplies the ground voltage GND via different wiring (not shown) provided to the print wiring substrate 23. Alternatively, one of the terminal TGND of the semiconductor device 21a or the terminal TGND of the semiconductor device 21b may be coupled to the node that supplies the ground voltage GND, and the terminal TGND of the semiconductor device 21a and the terminal TGND of the semiconductor device 21b may be coupled to each other via the wiring provided to the print wiring substrate 23.

The delay circuits 12a, 12b, 12c, and 12d are arranged on the upper surface of the print wiring substrate 23. The delay circuits 12a, 12b, 12c, and 12d are arranged in the −Y direction in the mentioned order. A set of the delay circuits 12a, 12b, 12c, and 12d is arranged between the semiconductor devices 21a and 21b.

The interconnects W1, W2, W3, W4, W7, W8, W11, W12, W13, W14, W15, W16, W17, and W18 are conductors having a line shape. W1, W2, W3, W4, W7, W8, W11, W12, W13, W14, W15, W16, W17, and W18 are arranged on the upper surface of the print wiring substrate 23.

One of the ends of the interconnect W1 overlaps and is in contact with the terminal LS of the semiconductor device 21a. The other of the ends of the interconnect W1 overlaps and is in contact with the terminal TGND of the semiconductor device 21a. Thus, the voltage of the terminal LS of the semiconductor device 21a is fixed to the ground voltage GND.

One of the ends of the interconnect W2 overlaps and is in contact with the terminal LS of the semiconductor device 21b. The other of the ends of the interconnect W2 overlaps and is in contact with the terminal TVDD of the semiconductor device 21b. Thus, the voltage of the terminal LS of the semiconductor device 21b is fixed to the power supply voltage VDD.

One of the ends of the interconnect W3 overlaps and is in contact with the terminal RFC of the semiconductor device 21a. The other of the ends of the interconnect W3 is coupled to the amplifier circuit 3.

One of the ends of the interconnect W4 overlaps and is in contact with the terminal RFC of the semiconductor device 21b. The other of the ends of the interconnect W4 is coupled to the antenna 5.

One of the ends of the interconnect W1l overlaps and is in contact with the terminal RF1 of the semiconductor device 21a. The other of the ends of the interconnect W1l is coupled to the input end of the delay circuit 12a.

One of the ends of the interconnect W12 is coupled to the output end of the delay circuit 12a. The other of the ends of the interconnect W12 overlaps and is in contact with the terminal RF4 of the semiconductor device 21b.

One of the ends of the interconnect W13 overlaps and is in contact with the terminal RF2 of the semiconductor device 21a. The other of the ends of the interconnect W13 is coupled to the input end of the delay circuit 12b.

One of the ends of the interconnect W14 is coupled to the output end of the delay circuit 12b. The other of the ends of the interconnect W14 overlaps and is in contact with the terminal RF3 of the semiconductor device 21b.

The semiconductor devices 21a and 21b have terminals arranged as described above with reference to FIG. 5, face opposite directions to each other, and have the relationship between the input (the voltages of the terminals LS, V1, and V2) and the output (the control signals SC1, SC2, SC3, and SC4) described above with reference to FIG. 4. Thus, the set of the terminal RF1 of the semiconductor device 21a and the terminal RF4 of the semiconductor device 21b coupled to each other via the delay circuit 12a is positioned outside the set of the terminal RF2 of the semiconductor device 21a and the terminal RF3 of the semiconductor device 21b coupled to each other via the delay circuit 12b. Thus, the interconnect W1l can extend from the terminal RF1 of the semiconductor device 21a to the input end of the delay circuit 12a without crossing the interconnect W13, and the interconnect W13 can extend from the terminal RF2 of the semiconductor device 21a to the input end of the delay circuit 12b without crossing the interconnect W11. Also, the interconnect W12 can extend from the output end of the delay circuit 12a to the terminal RF4 of the semiconductor device 21b without crossing the interconnect W14, and the interconnect W14 can extend from the output end of the delay circuit 12b to the terminal RF3 of the semiconductor device 21b without crossing the interconnect W12.

The interconnect W1l and the interconnect W13 may have any shape over the X-Y plane, provided that they do not cross each other. The interconnect W12 and the interconnect W14 may have any shape over the X-Y plane, provided that they do not cross each other. Although FIG. 6 shows the example in which each of the interconnects W11, W12, W13, and W14 has an L-shape, one or more of the interconnects W11, W12, W13, and W14 may be bent at two or more points.

One of the ends of the interconnect W15 overlaps and is in contact with the terminal RF3 of the semiconductor device 21a. The other of the ends of the interconnect W15 is coupled to the input end of the delay circuit 12c.

One of the ends of the interconnect W16 is coupled to the output end of the delay circuit 12c. The other of the ends of the interconnect W16 overlaps and is in contact with the terminal RF2 of the semiconductor device 21b.

One of the ends of the interconnect W17 overlaps and is in contact with the terminal RF4 of the semiconductor device 21a. The other of the ends of the interconnect W17 is coupled to the input end of the delay circuit 12d.

One of the ends of the interconnect W18 is coupled to the output end of the delay circuit 12d. The other of the ends of the interconnect W18 overlaps and is in contact with the terminal RF1 of the semiconductor device 21b.

The semiconductor devices 21a and 21b have terminals arranged as described above with reference to FIG. 5, face opposite directions to each other, and have the relationship between the input (the voltages of the terminals LS, V1, and V2) and the output (the control signals SC1, SC2, SC3, and SC4) described above with reference to FIG. 4. Thus, the set of the terminal RF4 of the semiconductor device 21a and the terminal RF1 of the semiconductor device 21b coupled to each other via the delay circuit 12d is positioned outside the set of the terminal RF3 of the semiconductor device 21a and the terminal RF2 of the semiconductor device 21b coupled to each other via the delay circuit 12c. Thus, the interconnect W15 can extend from the terminal RF3 of the semiconductor device 21a to the input end of the delay circuit 12c without crossing the interconnect W17, and the interconnect W17 can extend from the terminal RF4 of the semiconductor device 21a to the input end of the delay circuit 12d without crossing the interconnect W15. Also, the interconnect W16 can extend from the output end of the delay circuit 12c to the terminal RF2 of the semiconductor device 21b without crossing the interconnect W18, and the interconnect W18 can extend from the output end of the delay circuit 12d to the terminal RF1 of the semiconductor device 21b without crossing the interconnect W16.

The interconnect W15 and the interconnect W17 may have any shape over the X-Y plane, provided that they do not cross each other. The interconnect W16 and the interconnect W18 may have any shape over the X-Y plane, provided that they do not cross each other. Although FIG. 6 shows the example in which each of the interconnects W15, W16, W17, and W18 has an L-shape, one or more of the interconnects W15, W16, W17, and W18 may be bent at two or more points.

One of the ends of the interconnect W7 overlaps and is in contact with the terminal V1 of the semiconductor device 21a. The other of the ends of the interconnect W7 overlaps and is in contact with the terminal V2 of the semiconductor device 21b. The terminal V1 of the semiconductor device 21a and the terminal V2 of the semiconductor device 21b receive the same voltage via the interconnect W7.

One of the ends of the interconnect W8 overlaps and is in contact with the terminal V2 of the semiconductor device 21a. The other of the ends of the interconnect W8 overlaps and is in contact with the terminal V1 of the semiconductor device 21b. The terminal V2 of the semiconductor device 21a and the terminal V1 of the semiconductor device 21b receive the same voltage via the interconnect W8.

The semiconductor devices 21 have the relationship between the input (the voltages of the terminals LS, V1, and V2) and the output (the control signals SC1, SC2, SC3, and SC4) described above with reference to FIG. 4. Thus, with regard to the coupling between the terminal V1 and the terminal V2, the configuration shown in FIG. 2 is realized by the terminal V2 of the semiconductor device 21a being coupled to the terminal V1 of the semiconductor device 21b and the terminal V1 of the semiconductor device 21a being coupled to the terminal V2 of the semiconductor device 21b. The semiconductor devices 21 have terminals arranged as described above with reference to FIG. 5 and face opposite directions to each other. Thus, with regard to the positional relationship between the terminal V1 and the terminal V2 in the Y direction, the terminal V2 of the semiconductor device 21a and the terminal V1 of the semiconductor device 21b coupled to each other are positioned on the same side (the side in the −Y direction), and the terminal V1 of the semiconductor device 21a and the terminal V2 of the semiconductor device 21b coupled to each other are positioned on the same side (the side in the +Y direction). Thus, the interconnect W7 can extend from the terminal V1 of the semiconductor device 21a to the terminal V2 of the semiconductor device 21b without crossing the interconnect W8, and the interconnect W8 can extend from the terminal V2 of the semiconductor device 21a to the terminal V1 of the semiconductor device 21b without crossing the interconnect W7.

The interconnect W7 and the interconnect W8 may have any shape over the X-Y plane, provided that they do not cross each other. Although FIG. 6 shows the example in which each of the interconnects W7 and W8 has a shape in which two L-shapes are connected to each other, one or both of the interconnects W7 and W8 may be bent at three or more points.

Due to the arrangement and the coupling described above with reference to FIG. 6, one signal passage dynamically defined based on the voltage applied to the terminals V1 and V2 is formed between the terminal RFC of the semiconductor device 21a and the terminal RFC of the semiconductor device 21b, as is clear from FIG. 4 and as described below. As described above, the terminal LS of the semiconductor device 21a is coupled to the terminal TGND, and the terminal LS of the semiconductor device 21b is coupled to the terminal TVDD. Thus, it should be noted that because of this the terminal LS of the semiconductor device 21a receives the ground voltage GND, and that the terminal LS of the semiconductor device 21b receives the power supply voltage VDD.

In the semiconductor device 21a, the control signal SC1 has an ON level and the terminal RFC and the terminal RF1 are coupled to each other if the semiconductor device 21a receives the “0” voltage at both the terminal V1 and the terminal V2. Since the semiconductor device 21a receives the “0” voltage at both the terminal V1 and the terminal V2, the semiconductor device 21b receives the “0” voltage at both the terminal V1 and the terminal V2. Thus, in the semiconductor device 21b, the control signal SC4 has an ON level and the terminal RFC and the terminal RF4 are coupled to each other. Because of this, a signal passage is formed between the terminal RFC of the semiconductor device 21a and the terminal RFC of the semiconductor device 21b via the interconnect W11, the delay circuit 12a, and the interconnect W12. No signal passage via a set of the interconnect W13, the delay circuit 12b, and the interconnect W14 is formed, no signal passage via a set of the interconnect W15, the delay circuit 12c, and the interconnect W16 is formed, and no signal passage via a set of the interconnect W17, the delay circuit 12d, and the interconnect W18 is formed.

In the semiconductor device 21a, the control signal SC2 has an ON level and the terminal RFC and the terminal RF2 are coupled to each other if the semiconductor device 21a receives the “0” voltage at the terminal V1 and receives the “1” voltage at the terminal V2. Since the semiconductor device 21a receives the “0” voltage at the terminal V1 and receives the “1” voltage at the terminal V2, the semiconductor device 21b receives the “1” voltage at the terminal V1 and receives the “0” voltage at the terminal V2. Thus, in the semiconductor device 21b, the control signal SC3 has an ON level and the terminal RFC and the terminal RF3 are coupled to each other. Because of this, a signal passage is formed between the terminal RFC of the semiconductor device 21a and the terminal RFC of the semiconductor device 21b via the interconnect W13, the delay circuit 12b, and the interconnect W14. No signal passage via a set of the interconnect W11, the delay circuit 12a, and the interconnect W12 is formed, no signal passage via a set of the interconnect W15, the delay circuit 12c, and the interconnect W16 is formed, and no signal passage via a set of the interconnect W17, the delay circuit 12d, and the interconnect W18 is formed.

In the semiconductor device 21a, the control signal SC3 has an ON level and the terminal RFC and the terminal RF3 are coupled to each other if the semiconductor device 21a receives the “1” voltage at the terminal V1 and receives the “0” voltage at the terminal V2. Since the semiconductor device 21a receives the “1” voltage at the terminal V1 and receives the “0” voltage at the terminal V2, the semiconductor device 21b receives the “0” voltage at the terminal V1 and receives the “1” voltage at the terminal V2. Thus, in the semiconductor device 21b, the control signal SC2 has an ON level and the terminal RFC and the terminal RF2 are coupled to each other. Because of this, a signal passage is formed between the terminal RFC of the semiconductor device 21a and the terminal RFC of the semiconductor device 21b via the interconnect W15, the delay circuit 12c, and the interconnect W16. No signal passage via a set of the interconnect W11, the delay circuit 12a, and the interconnect W12 is formed, no signal passage via a set of the interconnect W13, the delay circuit 12b, and the interconnect W14 is formed, and no signal passage via a set of the interconnect W17, the delay circuit 12d, and the interconnect W18 is formed.

In the semiconductor device 21a, the control signal SC4 has an ON level and the terminal RFC and the terminal RF4 are coupled to each other if the semiconductor device 21a receives the “1” voltage at both the terminal V1 and the terminal V2. Since the semiconductor device 21a receives the “1” voltage at both the terminal V1 and the terminal V2, the semiconductor device 21b receives the “1” voltage at both the terminal V1 and the terminal V2. Thus, in the semiconductor device 21b, the control signal SC1 has an ON level and the terminal RFC and the terminal RF1 are coupled to each other. Because of this, a signal passage is formed between the terminal RFC of the semiconductor device 21a and the terminal RFC of the semiconductor device 21b via the interconnect W17, the delay circuit 12d, and the interconnect W18. No signal passage via a set of the interconnect W11, the delay circuit 12a, and the interconnect W12 is formed, no signal passage via a set of the interconnect W13, the delay circuit 12b, and the interconnect W14 is formed, and no signal passage via a set of the interconnect W15, the delay circuit 12c, and the interconnect W16 is formed.

According to the first embodiment, a switch device with simple internal coupling can be provided, as described below.

As in the first embodiment, a switch device having the same functions as those of the switch device 4 can be realized using the two same semiconductor devices. In this case, depending on the logical operation that the semiconductor device performs on the input (corresponding to the voltages of the terminals V1 and V2 of the first embodiment), the same input from the two semiconductor devices need to be connected to each other. That is, a semiconductor device that has the same terminals as the terminals of the semiconductor devices 21 and performs a logical operation different from the logical operation performed by the semiconductor devices 21 may be used in place of the semiconductor devices 21 shown in FIG. 6. The terminals V1 of the two semiconductor devices are coupled to each other, and the terminals V2 of the two semiconductor devices are coupled to each other. Since the semiconductor devices 21 face opposite directions and the sides having the terminals V1 and V2 of the semiconductor devices 21 are opposed to each other, the order in which the terminals V1 and V2 of the semiconductor device 21a are arranged in the +Y direction differs from the order in which the terminals V1 and V2 of the semiconductor device 21b are arranged in the +Y direction. Thus, the interconnect that mutually couples the terminals V1 and the interconnect that mutually couples the terminals V2 need to be crossed. Crossing the interconnects requires a via inside the print wiring substrate. However, manufacture of such a structure is complicated.

According to the first embodiment, the switch device 4 realizes the switch circuit 11, and includes the same two semiconductor devices 21a and 21b that couple the terminal RFC to the terminals RF1, RF2, RF3, or RF4 based on a combination of the voltages of the terminals V1 and V2. If the semiconductor devices 21 receive the “0” voltage at the terminal V1 and receive the “1” voltage at the terminal V2, the semiconductor device 21a couples the terminal RFC to the terminal RF2, and the semiconductor device 21b couples the terminal RFC to the terminal RF3. If the semiconductor devices 21 receive the “1” voltage at the terminal V1 and receive the “0” voltage at the terminal V2, the semiconductor device 21a couples the terminal RFC to the terminal RF3, and the semiconductor device 21b couples the terminal RFC to the terminal RF2. Also, the semiconductor devices 21a and 21b face opposite directions to each other, the sides having the terminals V1 and V2 of the semiconductor devices 21a and 21b are opposed to each other, the terminal V1 of the semiconductor device 21a is coupled to the terminal V2 of the semiconductor device 21b, and the terminal V2 of the semiconductor device 21a is coupled to the terminal V1 of the semiconductor device 21b. Thus, if a signal passage from the terminal RF2 of the semiconductor device 21a to the terminal RF3 of the semiconductor device 21b and a signal passage from the terminal RF3 of the semiconductor device 21a to the terminal RF2 of the semiconductor device 21b are formed, it is possible to select one of two signal passages by applying the “0” voltage to the terminal V1 of the semiconductor device 21a and applying the “1” voltage to the terminal V2 of the semiconductor device 21a or by applying the “1” voltage to the terminal V1 of the semiconductor device 21a and applying the “0” voltage to the terminal V2 of the semiconductor device 21a. As a result, the switch device 4 that switches two signal passages using the two same devices is realized.

Also, if the semiconductor devices 21 receive different voltages at the terminals V1 and V2, as described above, either an operation in which the semiconductor device 21a selects the terminal RF2 and the semiconductor device 21b selects the terminal RF3 or an operation in which the semiconductor device 21a selects the terminal RF3 and the semiconductor device 21b selects the terminal RF2 is performed. To implement such operations, the terminal V1 of the semiconductor device 21a is coupled to the terminal V2 of the semiconductor device 21b, and the terminal V2 of the semiconductor device 21a is coupled the terminal V1 of the semiconductor device 21b. Thus, it is unnecessary to cross the interconnects W7 and W8. As a result, the switch device 4 with simple internal coupling can be realized.

### 2. Second Embodiment

A second embodiment is based on the first embodiment and relates to the arrangement of the terminal TVDD.

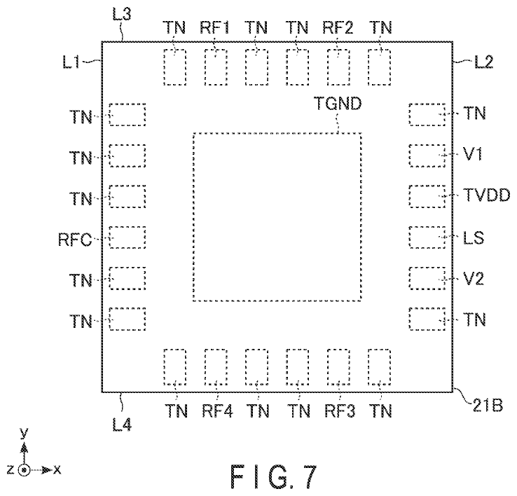

FIG. 7 shows an example of a structure of a switch circuit of a switch device of the second embodiment. The switch circuit 11 of a switch device 4B of the second embodiment is realized as a semiconductor device 21B. As shown in FIG. 7, the terminal TVDD is arranged between the terminal V1 and the terminal V2.

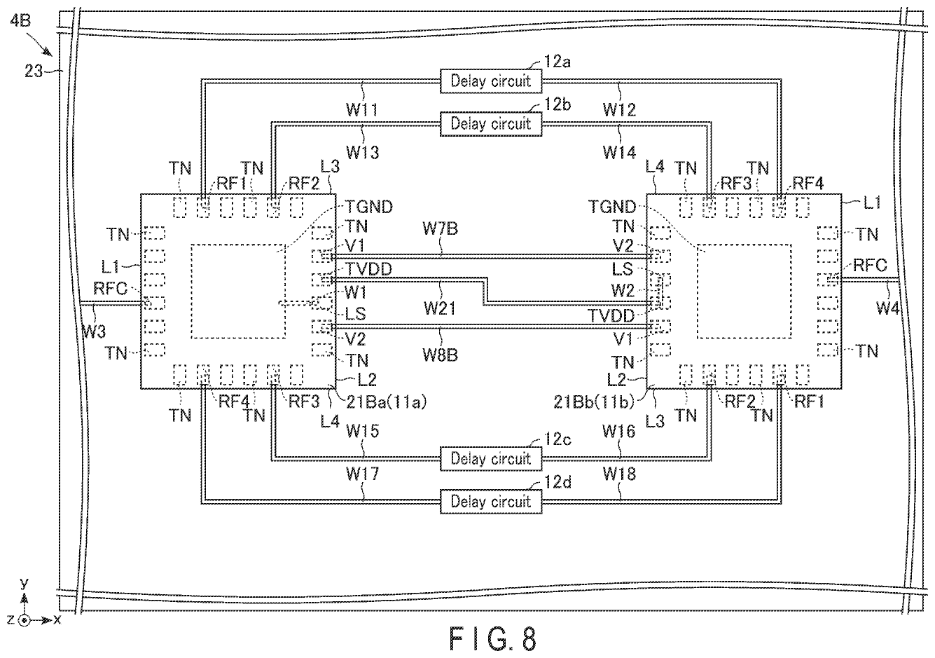

FIG. 8 shows an example of a partial structure of the switch device of the second embodiment and shows the arrangement of the components of the switch device along the X-Y plane. As shown in FIG. 8, the terminal V1 and the terminal V2 are spaced from each other without being adjacent to each other based on the arrangement of the terminal TVDD between the terminal V1 and the terminal V2. Depending on the arrangement of the terminal V1 and the terminal V2, the terminal V1 of the semiconductor device 21Ba and the terminal V2 of the semiconductor device 21Bb are arranged in the +X direction, and the terminal V2 of the semiconductor device 21Ba and the terminal V1 of the semiconductor device 21Bb are arranged in the +X direction. FIG. 8 shows such an example. Based on the arrangement shown as an example in FIG. 8, the interconnects W7B and W8B in the second embodiment have a linear shape.

The switch device 4B further includes an interconnect W21. The interconnect W21 is a conductor having a line shape and is arranged on the upper surface of the print wiring substrate 23. One of the ends of the interconnect W21 overlaps and is in contact with the terminal TVDD of the semiconductor device 21a. The other of the ends of the interconnect W21 overlaps and is in contact with the terminal TVDD of the semiconductor device 21b. In one example, the interconnect W21 has a shape in which two L-shapes are connected to each other.

According to the second embodiment, it is possible to achieve the same advantageous effects as in the first embodiment. In addition, according to the second embodiment, the terminal TVDD is arranged between the terminal V1 and the terminal V2. Thus, the interconnect W21 can be arranged without crossing the interconnects W7B and W8B. As a result, the switch device 4B with simple internal coupling can be realized.

### 3. Third Embodiment

A third embodiment differs from the second embodiment in the positions of the terminals V1 and V2 based on the second embodiment.

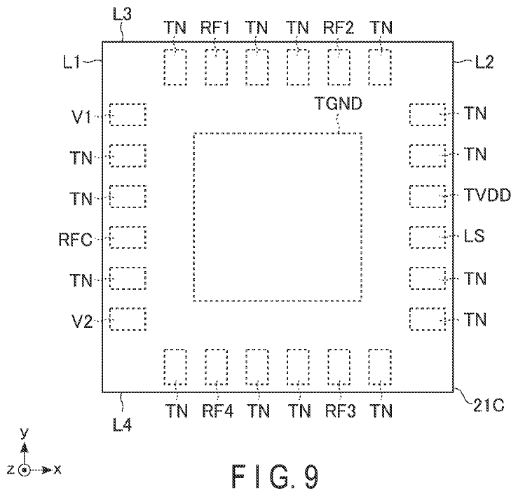

FIG. 9 shows an example of a structure of a switch circuit of a switch device of the third embodiment. The switch circuit 11 of a switch device 4C of the third embodiment is realized as a semiconductor device 21C. As shown in FIG. 9, the terminals V1 and V2 face the first side L1, and the terminal RFC is interposed between the terminals V1 and V2. In one example, the terminal V1 is positioned farthest in the +Y direction among the terminals arranged along the first side L1, and the terminal V2 is positioned farthest in the −Y direction among the terminals arranged along the first side L1.

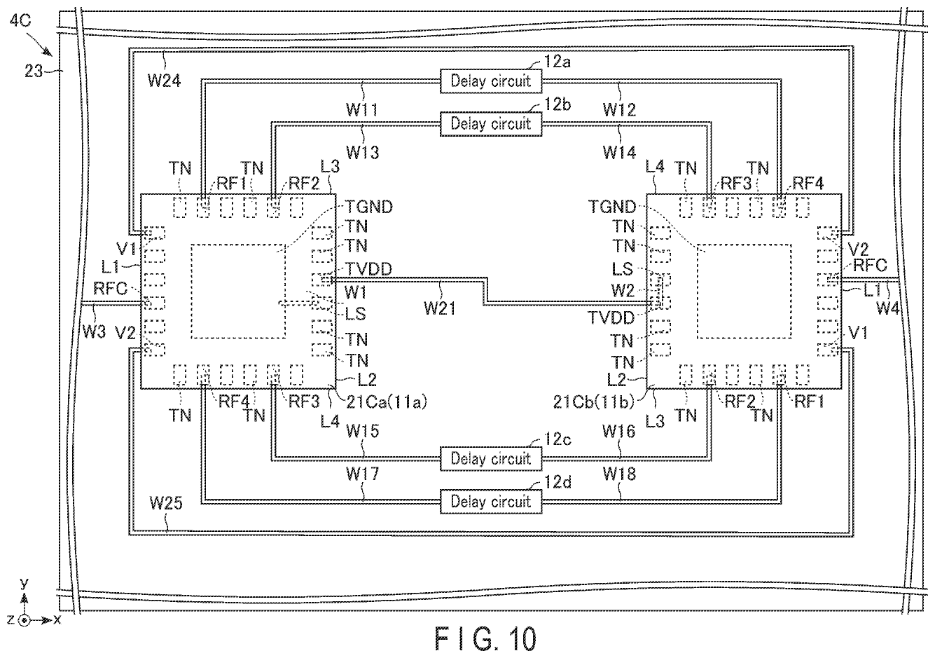

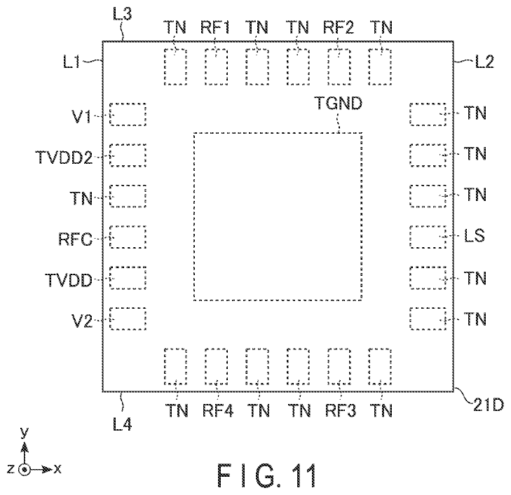

FIG. 10 shows an example of a partial structure of the switch device of the third embodiment and shows the arrangement of the components of the switch device along the X-Y plane. As shown in FIG. 10, the switch device 4C does not include the interconnect W7B or W8B, but includes interconnects W24 and W25. The interconnects W24 and W25 are conductors having a linear shape and are arranged on the upper surface of the print wiring substrate 23.

One of the ends of the interconnect W24 overlaps and is in contact with the terminal V1 of the semiconductor device 21Ca. The other of the ends of the interconnect W24 overlaps and is in contact with the terminal V2 of the semiconductor device 21Cb. The interconnect W24 is positioned outside a region formed of the set of semiconductor devices 21Ca and 21Cb, and is arranged in the +Y direction with respect to the interconnect W11, the delay circuit 12a, and the interconnect W12.

One of the ends of the interconnect W25 overlaps and is in contact with the terminal V2 of the semiconductor device 21Ca. The other of the ends of the interconnect W25 overlaps and is in contact with the terminal V1 of the semiconductor device 21Cb. The interconnect W25 is positioned outside a region formed of the set of semiconductor devices 21Ca and 21Cb, and is arranged in the −Y direction with respect to the interconnect W17, the delay circuit 12d, and the interconnect W18.

According to the third embodiment, it is possible to achieve the same advantageous effects as in the first and second embodiments. Also, according to the third embodiment, the terminals V1 and V2 face the first side L1, and the terminal RFC is interposed between the terminals V1 and V2. Thus, the terminals V1 and V2 are not positioned in a region surrounded with the semiconductor devices 21Ca and 21Cb, the interconnects W11, W12, W17, and W18, and the delay circuits 12a and 12d. Accordingly, the interconnect coupling the terminal V1 of the semiconductor device 21Ca to the control circuit 13 and the interconnect coupling the terminal V2 of the semiconductor device 21Ca to the control circuit 13 need not cross any of the interconnects W11, W12, W13, W14, W15, W16, W17, and W18. As a result, signals passing through the interconnects W11, W12, W13, W14, W15, W16, W17, and W18 are not affected by the voltages passing through the interconnect coupling the terminal V1 of the semiconductor device 21Ca to the control circuit 13 and the interconnect coupling the terminal V2 of the semiconductor device 21Ca to the control circuit 13. In other words, the noise that signals passing through the interconnects W11, W12, W13, W14, W15, W16, W17, and W18 receive is suppressed.

### 4. Fourth Embodiment

A fourth embodiment is based on the third embodiment and differs from the third embodiment in the position of the terminal TVDD.

FIG. 11 shows an example of a structure of a switch circuit of a switch device of the fourth embodiment. The switch circuit 11 of a switch device 4D of the fourth embodiment is realized as a semiconductor device 21D. As shown in FIG. 11, the semiconductor device 21D includes a terminal TVDD2. The terminal TVDD2 is coupled to the terminal TVDD inside the switch device 4D. The terminals TVDD and TVDD2 face the first side L1. The terminal TVDD is arranged between the terminal RFC and the terminal V2. The terminal TVDD2 is arranged between the terminal V1 and the terminal RFC. The position of the terminal TVDD and the position of the terminal TVDD2 may be reversed.

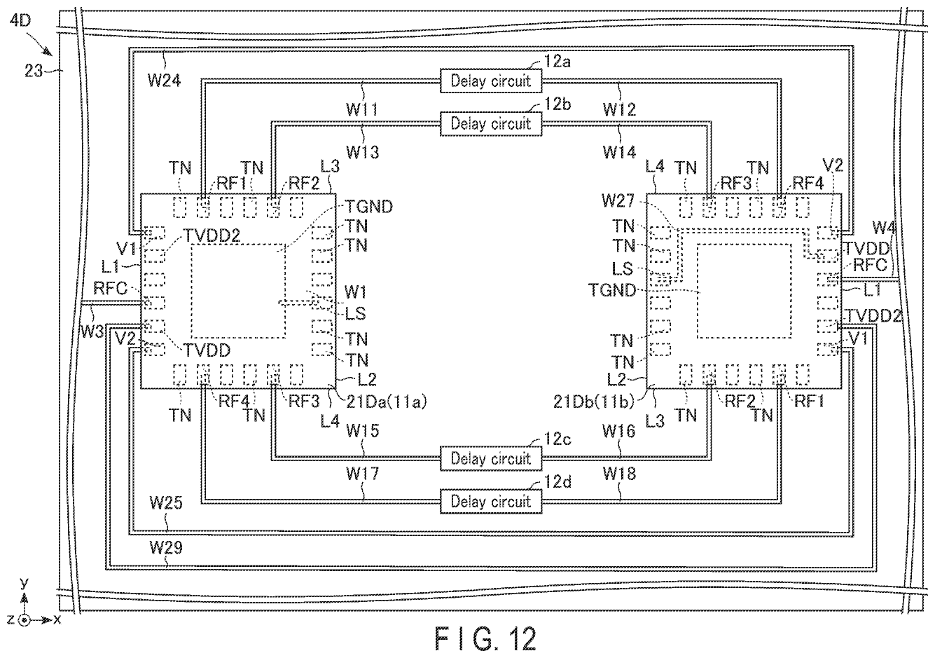

FIG. 12 shows an example of a partial structure of the switch device of the fourth embodiment and shows the arrangement of the components of the switch device along the X-Y plane. As shown in FIG. 12, the switch device 4D does not include the interconnect W2 or W21 but includes interconnects W27 and W29. The interconnects W27 and W29 are conductors having a line shape and are arranged on the upper surface of the print wiring substrate 23.

The interconnect W27 is arranged between the print wiring substrate 23 and the semiconductor device 21Db. One of the ends of the interconnect W27 overlaps and is in contact with the terminal LS of the semiconductor device 21Db. The other of the ends of the interconnect W27 overlaps and is in contact with the terminal TVDD of the semiconductor device 21Db.

One of the ends of the interconnect W29 overlaps and is in contact with the terminal TVDD of the semiconductor device 21Da. The other of the ends of the interconnect W29 overlaps and is in contact with the terminal TVDD2 of the semiconductor device 21Db. The interconnect W29 is positioned outside a region formed of the set of semiconductor devices 21Da and 21Db, and is arranged in the −Y direction with respect to the interconnect W25.

The interconnect W29 may be in contact with the terminal TVDD2 of the semiconductor device 21Da and the terminal TVDD of the semiconductor device 21Db. In this case, the interconnect W29 is positioned outside a region formed of the set of semiconductor devices 21Da and 21Db, and is arranged in the +Y direction with respect to the interconnect W24.

According to the fourth embodiment, it is possible to achieve the same advantageous effects as in the first to third embodiments. Also, the semiconductor device 21D of the fourth embodiment includes the terminal TVDD2, and the terminals TVDD and TVDD2 face the first side L1. Thus, in the switch device 4D, the terminals TVDD and TVDD2 are not positioned in a region surrounded with the semiconductor devices 21Da and 21Db, the interconnects W11, W12, W17, and W18, and the delay circuits 12a and 12d. As a result, signals passing through the interconnects W11, W12, W13, W14, W15, W16, W17, and W18 are not affected by the voltage passing through the interconnect coupling the terminal TVDD of the semiconductor device 21Da to the control circuit 13. That is, the noise that signals passing through the interconnects W11, W12, W13, W14, W15, W16, W17, and W18 receive is suppressed.

The terminal TVDD2 and the terminal V1 may be replaced with each other, and the terminal TVDD and the terminal V2 may be replaced with each other. In this case, the interconnect W25 is arranged in the −Y direction with respect to the interconnect W29.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A switch device comprising:
a first semiconductor device and a second semiconductor device,
each of the first semiconductor device and the second semiconductor device including: a first side; a second side and a third side facing each other; a first terminal; a second terminal facing the second side; a third terminal facing the third side; a fourth terminal and a fifth terminal arranged along the first side; and a sixth terminal,
each of the first semiconductor device and the second semiconductor device coupling the first terminal to the second terminal while the sixth terminal is receiving a first voltage, the fourth terminal is receiving a second voltage, and the fifth terminal is receiving a third voltage, and
each of the first semiconductor device and the second semiconductor device coupling the first terminal to the third terminal while the sixth terminal is receiving a fourth voltage, the fourth terminal is receiving the third voltage, and the fifth terminal is receiving the second voltage;
a first delay circuit configured to supply, to the third terminal of the second semiconductor device, a signal obtained by delaying a signal at an input end coupled to the second terminal of the first semiconductor device;
a first conductor coupled to the fourth terminal of the first semiconductor device and the fifth terminal of the second semiconductor device; and
a second conductor coupled to the fifth terminal of the first semiconductor device and the fourth terminal of the second semiconductor device,
wherein
the first side of the first semiconductor device faces the first side of the second semiconductor device,
the sixth terminal of the first semiconductor device is coupled to a terminal receiving the first voltage, and
the sixth terminal of the second semiconductor device is coupled to a terminal receiving the fourth voltage.

2. The switch device according to claim 1, further comprising a second delay circuit configured to supply, to the second terminal of the second semiconductor device, a signal obtained by delaying a signal at an input end coupled to the third terminal of the first semiconductor device,
wherein each of the first semiconductor device and the second semiconductor device:
couples the first terminal to the third terminal while the sixth terminal is receiving the first voltage, the fourth terminal is receiving the third voltage, and the fifth terminal is receiving the second voltage; and
couples the first terminal to the second terminal while the sixth terminal is receiving the fourth voltage, the fourth terminal is receiving the second voltage, and the fifth terminal is receiving the third voltage.

3. The switch device according to claim 2, wherein each of the first semiconductor device and the second semiconductor device:
further includes a seventh terminal facing the second side and an eighth terminal facing the third side,
couples the first terminal to the seventh terminal while the sixth terminal is receiving the first voltage, the fourth terminal is receiving the second voltage, and the fifth terminal is receiving the second voltage, and while the sixth terminal is receiving the fourth voltage, the fourth terminal is receiving the third voltage, and the fifth terminal is receiving the third voltage, and
couples the first terminal to the eighth terminal while the sixth terminal is receiving the first voltage, the fourth terminal is receiving the third voltage, and the fifth terminal is receiving the third voltage, and while the sixth terminal is receiving the fourth voltage, the fourth terminal is receiving the second voltage, and the fifth terminal is receiving the second voltage.

4. The switch device according to claim 3, further comprising:
a third delay circuit configured to supply, to the eighth terminal of the second semiconductor device, a signal obtained by delaying a signal at an input end coupled to the seventh terminal of the first semiconductor device; and
a fourth delay circuit configured to supply, to the seventh terminal of the second semiconductor device, a signal obtained by delaying a signal at an input end coupled to the eighth terminal of the first semiconductor device.

5. The switch device according to claim 1, wherein:
each of the first semiconductor device and the second semiconductor device further includes a ninth terminal receiving the fourth voltage and arranged between the fourth terminal and the fifth terminal, and
the switch device further comprises a third conductor coupled to the ninth terminal of the first semiconductor device and the ninth terminal of the second semiconductor device.

6. A switch device comprising:
a first semiconductor device and a second semiconductor device,
each of the first semiconductor device and the second semiconductor device including: a first side; a second side and a third side facing each other; a fourth side facing the first side; a first terminal; a second terminal facing the second side; a third terminal facing the third side; a fourth terminal and a fifth terminal arranged along the first side; and a sixth terminal,
each of the first semiconductor device and the second semiconductor device coupling the first terminal to the second terminal while the sixth terminal is receiving a first voltage, the fourth terminal is receiving a second voltage, and the fifth terminal is receiving a third voltage, and
each of the first semiconductor device and the second semiconductor device coupling the first terminal to the third terminal while the sixth terminal is receiving a fourth voltage, the fourth terminal is receiving the third voltage, and the fifth terminal is receiving the second voltage;
a first delay circuit configured to supply, to the third terminal of the second semiconductor device, a signal obtained by delaying a signal at an input end coupled to the second terminal of the first semiconductor device;
a first conductor coupled to the fourth terminal of the first semiconductor device and the fifth terminal of the second semiconductor device; and
a second conductor coupled to the fifth terminal of the first semiconductor device and the fourth terminal of the second semiconductor device,
wherein
the fourth side of the first semiconductor device faces the fourth side of the second semiconductor device,
the sixth terminal of the first semiconductor device is coupled to a terminal receiving the first voltage, and
the sixth terminal of the second semiconductor device is coupled to a terminal receiving the fourth voltage.

7. The switch device according to claim 6, further comprising a second delay circuit configured to supply, to the second terminal of the second semiconductor device, a signal obtained by delaying a signal at an input end coupled to the third terminal of the first semiconductor device,
wherein each of the first semiconductor device and the second semiconductor device:
couples the first terminal to the third terminal while the sixth terminal is receiving the first voltage, the fourth terminal is receiving the third voltage, and the fifth terminal is receiving the second voltage; and
couples the first terminal to the second terminal while the sixth terminal is receiving the fourth voltage, the fourth terminal is receiving the second voltage, and the fifth terminal is receiving the third voltage.

8. The switch device according to claim 7, wherein each of the first semiconductor device and the second semiconductor device:
further includes a seventh terminal facing the second side and an eighth terminal facing the third side,
couples the first terminal to the seventh terminal while the sixth terminal is receiving the first voltage, the fourth terminal is receiving the second voltage, and the fifth terminal is receiving the second voltage, and while the sixth terminal is receiving the fourth voltage, the fourth terminal is receiving the third voltage, and the fifth terminal is receiving the third voltage, and
couples the first terminal to the eighth terminal while the sixth terminal is receiving the first voltage, the fourth terminal is receiving the third voltage, and the fifth terminal is receiving the third voltage, and while the sixth terminal is receiving the fourth voltage, the fourth terminal is receiving the second voltage, and the fifth terminal is receiving the second voltage.

9. The switch device according to claim 8, further comprising:
a third delay circuit configured to supply, to the eighth terminal of the second semiconductor device, a signal obtained by delaying a signal at an input end coupled to the seventh terminal of the first semiconductor device; and
a fourth delay circuit configured to supply, to the seventh terminal of the second semiconductor device, a signal obtained by delaying a signal at an input end coupled to the eighth terminal of the first semiconductor device.

10. The switch device according to claim 6, wherein:
each of the first semiconductor device and the second semiconductor device further includes a ninth terminal facing the fourth side and receiving the fourth voltage, and
the switch device further comprises a third conductor coupled to the ninth terminal of the first semiconductor device and the ninth terminal of the second semiconductor device.

11. The switch device according to claim 6, wherein:
each of the first semiconductor device and the second semiconductor device further includes a ninth terminal facing the first side and receiving the fourth voltage, and
the switch device further comprises a third conductor coupled to the ninth terminal of the first semiconductor device and the ninth terminal of the second semiconductor device.
